(19) United States
(12) Patent Application Publication
(10) Pub. No.: US 2005/0212107 A1
(43) Pub. Date: Sep. 29, 2005

(54) Circuit device and manufacturing method thereof

(76) Inventor: Atsushi Kato, Gunma (JP)

Correspondence Address: FISH & RICHARDSON P.C., CITIGROUP CENTER 52ND FLOOR, 153 EAST 53RD STREET, NEW YORK, NY, 10022-4611, US

(21) Appl. No.: 11/047,175

(22) Filed: Jan. 31, 2005

(30) Foreign Application Priority Data
Mar. 29, 2004 (JP) P2004-096959

(51) Int. Cl. H01L 23/02

(52) U.S. Cl. 257/678

(57) ABSTRACT

In the case of mounting a passive element in a circuit device, since an electrode part is tin-plated, the passive element is fixed to a mounting land part by use of a solder material, and wires cannot intersect with each other in a single layer. Accordingly, there are problems such as an increase in a mounting area, a restriction to a reflow temperature in mounting on a printed board, and deterioration of reliability due to solder crack after packaging. The electrode part of the passive element is gold-plated, and a bonding wire is directly fixed to the electrode part. Thus, a packaging density can be improved. Moreover, a package structure using no supporting substrate is adopted, and the passive element is bonded to an isolation trench. Thus, even in a structure having the bonding wire fixed therein, an increase in a package thickness is suppressed.

### BACKGROUND OF THE INVENTION

1. Field of the Invention

The present invention relates to a circuit device including a passive element and a manufacturing method thereof, and more particularly relates to a circuit device having an improved wiring density and a manufacturing method thereof.

2. Description of the Related Art

With reference to FIGS. 9A and 9B, a conventional circuit device will be described. FIG. 9A is a plan view of the circuit device, and FIG. 9B is a cross-sectional view along the line B-B in FIG. 9A.

As shown in FIG. 9A, a semiconductor element 101 such as an IC, for example, and a plurality of conductive patterns 103 are arranged in a predetermined package region 120 on a supporting substrate 110, for example. The conductive patterns 103 include a pad part 103a to which a bonding wire 108 or the like is fixed, and/or mounting land parts 103b to which both electrode parts 107 of a passive element 106 are fixed. The passive element 106 is, for example, a chip condenser or the like.

The passive element 106 and the semiconductor element 101 are connected to each other through the conductive patterns 103. Specifically, the electrode part 107 of the passive element 106 is fixed to the mounting land part 103b by use of a solder material 160, Ag paste or the like, and the conductive pattern 103 is extended from the mounting land part 103b. Thereafter, the pad part 103a and an electrode pad 102 of the semiconductor element 101 are connected to each other through the bonding wire 108 or the like. Moreover, the passive elements 106 are connected to each other through the conductive pattern 103 having the mounting land parts 103b on its both ends.

As shown in FIG. 9B, a side of an end of the passive element 106 is tin-plated to form the electrode part 107. In mounting the passive element 106, the element is fixed to the mounting land parts 103b (the conductive pattern 103) by use of the solder material (or a conductive adhesive) 160. This technology is described for instance in Japanese Patent Application Publication No. 2003-297601.

The electrode part 107 of the passive element 106 is formed by tin plating, which is inexpensive. Since tin has a low melting point and cannot be subjected to thermocompression bonding at a high temperature, the electrode part 107 is fixed to the conductive pattern 103 by use of the solder material (or the conductive adhesive) 160 in mounting the passive element 106.

In the case of mounting by use of the solder material 160, a fillet made of the solder material 160 is formed in the electrode part 107. Therefore, in order to electrically connect the passive element 106 to the semiconductor element 101, another passive element 106, or the conductive pattern 103, the mounting land part 103b larger than the electrode part 107 is required below the electrode part 107 of the passive element 106. Alternatively, the conductive pattern 103 having the pad part 103a connected to the bonding wire 108 is required. For the reasons described above, reduction in a mounting area makes little progress, and a product packaging density of the circuit device having the passive element 106 mounted thereon is lowered.

Moreover, if wiring becomes complicated and the conductive patterns 103 intersect with each other, a multi-layered structure is formed as indicated by the broken lines in FIG. 9A, and connections are made through through-holes TH. Alternatively, in the case of a single layer structure, it is required to arrange the conductive patterns 103 so as to make a long detour. Specifically, there are problems that, for the connection of the passive element, the multi-layered structure has to be formed by increasing costs and the number of production process, or the mounting area has to be further increased.

Furthermore, in the case of fixing by use of the solder material, a device having a structure subjected to plastic molding, has the following problems.

For example, a reflow temperature in mounting on a printed board or the like cannot be set to a melting point of solder or more. This is because, if the reflow temperature reaches the melting point of solder or more, solder is remelted to cause short circuit or package destruction.

Moreover, if the package is distorted by heat generated after plastic molding, crack occurs in solder or Ag paste. Thus, reliability is deteriorated.

Moreover, a circuit device using lead-free solder mainly made of tin as fixing means has another problem. For example, in the case where an external terminal (external electrode) of a package is fixed to a package board such as a printed board by use of the lead-free solder, or in the case where the external electrode itself is formed of solder, if solder is used for fixing in the package, the solder is required to have a melting point higher than that of the lead-free solder. However, mounting by use of high melting point solder also leads to a problem such as destruction of elements.

Moreover, in the case where the lead-free solder is used for fixing in the package, fixing means outside of the package is mounted by use of low melting point solder. Accordingly, fixing strength is not perfect.

Furthermore, there is a small variety of the lead-free solder, and there is not much difference in the melting point therebetween. Specifically, if a passive element in the package is fixed by use of the lead-free solder, and the external terminal (external electrode) is also fixed to the package board by use of the lead-free solder, there arises a problem since the lead-free solder inside is remelted.

### SUMMARY OF THE INVENTION

The present invention provides a circuit device that includes conductive patterns embedded in an insulating resin, a semiconductor element electrically connected to the conductive patterns, bonding wires, and a passive element which is embedded in a region of the insulating resin, other than a region where the conductive patterns are embedded, and has electrode parts provided on its both sides. In the circuit device, a bottom of the passive element is positioned lower than a surface of the conductive pattern, and one end of the bonding wire is fixed to the electrode part of the passive element.

The present invention also provides a method for manufacturing a circuit device that includes the steps of preparing a conductive foil, forming isolation trenches shallower than a thickness of the conductive foil in the conductive foil in a package region of a circuit element, and forming conductive patterns separated by the isolation trenches, fixing a passive element to the isolation trench, fixing one end of a bonding wire to an electrode part of the passive element, and fixing the other end thereof to any of a semiconductor element, the conductive pattern and another passive element, performing common molding by use of an insulating resin so as to entirely cover the package region of the circuit element and to fill the isolation trenches with the insulating resin, individually separating the conductive patterns by etching the conductive foil below the isolation trenches reach to the isolation trenches, and separating the passive element from the conductive pattern, and dividing the insulating resin for each package region of the circuit element by dicing.

The present invention can achieve the following effects.

First, the passive element can be directly and electrically connected to the semiconductor element, the conductive pattern or another passive element by use of the bonding wire. Specifically, a mounting land part for fixing the electrode part of the passive element, and a pad part for connection to an electrode pad of the semiconductor element are not required. Thus, reduction in a mounting area can be realized.

Second, by fixing the bonding wire directly to the passive element, electrical connection to other constituent components is realized. Thus, a part of the conductive pattern can be disposed below the bonding wire. In a conventional case, since the passive element is connected to the other constituent components by use of the conductive pattern, if the conductive pattern intersects with the conductive pattern connected to the passive element, it is required to form a two-layered wiring structure. Meanwhile, according to an embodiment of the present invention, the conductive patterns can intersect with each other in a single layer structure. Thus, a packaging density can be improved.

Third, the passive element is generally thicker than the semiconductor element, and a loop height is increased when electrical connection is made through the bonding wire. However, by fixing the passive element lower than the surface of the conductive pattern, an increase in a package thickness can be suppressed. To be more specific, a thickness equivalent to the conductive pattern can be reduced by adopting a package using no package board and fixing the passive element to the isolation trench. Thus, the loop height can be lowered even if the bonding wire is adopted, and the package thickness can be reduced.

Fourth, the passive element can be mounted by use of an adhesive or an adhesive sheet. Thus, there is no longer a restriction that a reflow temperature in mounting a module of the circuit device on a printed board must be set to not more than a melting point of solder.

Fifth, since fixing can be performed without using a solder material, occurrence of cracks in the solder material due to stress on a resin package can be prevented. Thus, reliability is improved.

Sixth, since a fillet made of the solder material is not formed on the side of the passive element, an area for mounting the passive element can be reduced. Thus, the packaging density of the entire device can be improved.

Seventh, in a circuit device using lead-free solder as fixing means, lead-free solder can be used to fix an external terminal (external electrode) to the package board. Alternatively, lead-free solder can be adopted for the external electrode itself.

Since there is a small variety of lead-free solder, and there is no difference in a melting point therebetween, lead-free solder cannot be used in both of the inside of the package and the outside of the package. According to the embodiment, since the bonding wire is used for electrical connection of the passive element in the package, lead-free solder can be used for connection between the external terminal and the package board.

Eighth, since the mounting land part which has been heretofore required for electrical connection of the passive element is no longer required, the passive element can be disposed close to the semiconductor element. Therefore, noise is absorbed well in the case where the passive element is, for example, a chip condenser.

Moreover, according to the manufacturing method of the present invention, the isolation trenches separating the conductive patterns have bottoms in an initial stage of the manufacturing steps, and the conductive patterns are the continuous conductive foil. Thus, the passive element can be fixed to the bottom. The bottoms of the isolation trenches are portions to be removed during the manufacturing steps. The passive element can be disposed between the conductive patterns by fixing the passive element by use of an adhesive having a predetermined thickness, and can be supported by the insulating resin. For example, in the case where the passive element is mounted on a supporting substrate, the semiconductor element and the passive element are mounted on the same surface. Thus, the package thickness is increased. However, according to the embodiment, a fixing surface for the passive element can be positioned lower than the surface of the conductive pattern (a fixing surface for the semiconductor element). Thus, even in the case where a relatively thick passive element is integrated with the semiconductor element, the package can be reduced in thickness.

Moreover, only the insulating resin may be cut in dicing performed to divide the insulating resin for each package region. Thus, life of a dicing blade can be extended since the blade never cuts the conductive foil. Moreover, there is no occurrence of metal burr caused when the conductive foils is cut.

Furthermore, compared to the case of mounting on a ceramic substrate, a step of forming a through-hole, a step of printing a conductor and the like can be omitted. There is an advantage that the manufacturing steps can be significantly shortened compared to the conventional case. Moreover, no frame mold is required, and the manufacturing method realizes a very quick delivery.

### BRIEF DESCRIPTION OF THE DRAWINGS

FIG. 1A is a plan view and FIG. 1B is a cross-sectional view showing a circuit device of the preferred embodiment.

FIG. 2A is a cross-sectional view and FIG. 2B is a plan view showing a method for manufacturing a circuit device of the preferred embodiment.

FIG. 3 is a cross-sectional view showing the method for manufacturing a circuit device of the preferred embodiment.

FIG. 4A is a cross-sectional view and FIG. 4B is a plan view showing the method for manufacturing a circuit device of the preferred embodiment.

FIG. 5 is a cross-sectional view showing the method for manufacturing a circuit device of the preferred embodiment.

FIG. 6 is a cross-sectional view showing the method for manufacturing a circuit device of the preferred embodiment.

FIG. 7A is a cross-sectional view and FIG. 7B is a plan view showing the method for manufacturing a circuit device of the preferred embodiment.

FIG. 8 is a cross-sectional view showing the method for manufacturing a circuit device of the preferred embodiment.

FIG. 9A is a plan view and FIG. 9B is a cross-sectional view showing a conventional circuit device.

### DESCRIPTION OF THE EMBODIMENTS

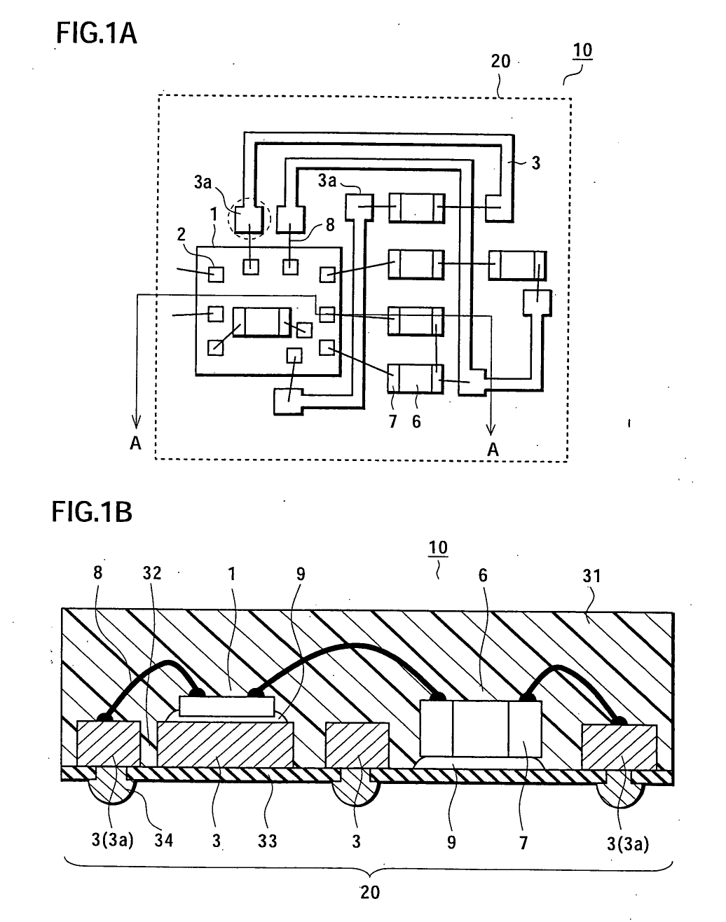

With reference to FIGS. 1 to 8, an embodiment of a circuit device of the present invention will be described.

FIGS. 1A and 1B show the circuit device of this embodiment. FIG. 1A is a plan view, and FIG. 1B is a cross-sectional view along the line A-A in FIG. 1A.

The circuit device 10 of this embodiment includes a semiconductor element 1, conductive patterns 3, passive elements 6, and bonding wires 8.

As shown in FIG. 1A, in the circuit device 10 of this embodiment, at least the semiconductor element 1 such as an IC, the conductive patterns 3, and the passive elements 6 are embedded and supported by use of an insulating resin in a package region 20 indicated by the broken line. Thus, a predetermined circuit is formed. The conductive pattern 3 has a pad part 3a on its end, to which the bonding wire 8 is fixed.

In this embodiment, the passive element 6 is a chip element having electrode parts 7 on its both ends, such as a chip resistor, a chip condenser, an inductance, a thermistor, an antenna, and an oscillator, for example. The electrode parts 7 are formed on the both ends of the passive element 6 formed to be long and narrow, and surfaces thereof are gold-plated. The passive elements 6 are bonded with an insulating adhesive material, for example, in a region where no conductive patterns 3 are disposed within the package region 20.

In this embodiment, electrical connection is realized not by directly fixing the electrode part 7 of the passive element 6 to the conductive pattern (a mounting land part) by use of a solder material or Ag paste, but by fixing one end of the bonding wire 8 to the electrode part 7.

The other end of the bonding wire 8 fixed to the passive element 6 is connected to an electrode pad 2 of the semiconductor element 1 and/or the pad part 3a of the conductive pattern 3. Alternatively, the electrode parts 7 of the passive element 6 are connected to each other through the bonding wire 8.

Thus, the electrode parts 7 are gold-plated so as to enable bonding through the bonding wire 8. Specifically, metal on an uppermost surface of the electrode part 7 is determined based on a material (Au, Al or the like) of the bonding wire 8.

Specifically, it is important that the passive element 6 is connected by use of a bonding wire without using the solder material, the Ag paste or the like.

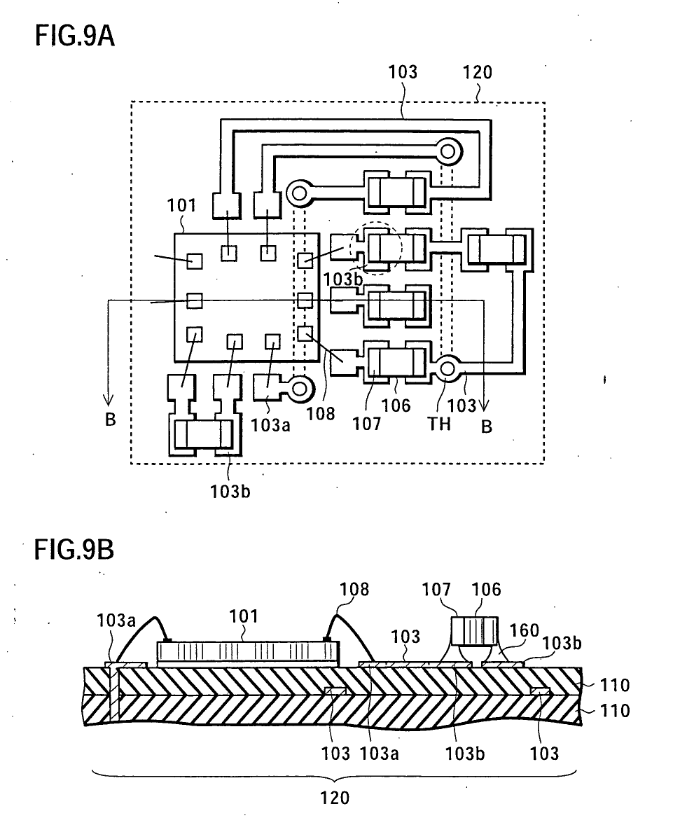

Accordingly, the mounting land part 103b (indicated by the broken circle in FIG. 9A) becomes unnecessary, to which an electrode part of a passive element has been heretofore fixed. Specifically, the pad part 3a of the conductive pattern 3 is not required to have a size which enables fixing of the electrode part 7. It is only necessary to secure an area which enables wire bonding.

Note that, also in this embodiment, in the case where the passive element 6 distant from the semiconductor element 1 is connected to the semiconductor element 1, the conductive pattern 3 is extended. Thus, it is required to provide the pad part 3a (indicated by the broken circle in FIG. 1A) close to the electrode pad 2 of the semiconductor element 1, and to have the passive element 6 wire-bonded thereto. However, also in the case where the conductive pattern 3 is extended as described above, for example, the conductive pattern 3 can be provided below the bonding wire 8 connected to the passive element 6. In other words, an increase in a mounting area can be prevented.

Moreover, with reference to the cross-sectional view of FIG. 1B, description will be given of a state of the semiconductor element 1 and the passive element 6.

The semiconductor element 1 is fixed onto the conductive pattern 3 to be an island by use of a conductive or insulating adhesive and the like according to usage.

The passive element 6 is bonded with an adhesive 9 in the region where no conductive patterns 3 are disposed within the package region 20. Note that, as described later, although the passive element 6 of this embodiment is bonded to the adhesive 9, the passive element 6 is supported by an insulating resin 31.

The adhesive 9 bonded to the passive element 6 is an adhesive resin or an adhesive sheet. Specifically, no fillet is formed unlike the case of the solder material 160. Therefore, a mounting area required to mount the passive element 6 is about the same as a planar size of the passive element 6.

As shown in FIG. 1B, in a spot where the passive element 6 and the semiconductor element 1 are close to each other, connection is directly made by the bonding wire 8.

Furthermore, below the bonding wire 8 having one end fixed to the passive element 6, a part of the conductive pattern 3 can be disposed. If the wires intersect with each other as described above, it has been heretofore required to form the conductive patterns to have a multi-layered wiring structure, and to make connections through through-holes. However, in this embodiment, the wires can intersect with each other in a single layer structure.

As described above, in this embodiment, electrical connection is realized by fixing the bonding wire 8 to the passive element 6. The passive element 6 such as the chip condenser, in particular, has a thickness larger than that of the semiconductor element 1, in general. Thus, if the passive element 6 is fixed to the same surface as that of the semiconductor element 1, in other words, fixed onto the conductive pattern 3 in the same way as the semiconductor element 1, a thickness of the conductive pattern 3, the thickness of the passive element 6 and a loop height of the bonding wire 8 make up a height of the circuit device 10. Accordingly, a package thickness is increased.

Consequently, in this embodiment, a package structure having no package board is adopted, and the passive element 6 is fixed in a position lower than a surface of the conductive pattern 3.

Thus, since the passive element 6 can be fixed in a lower position by the thickness of the conductive pattern 3, the circuit device of this embodiment can be realized without increasing the package thickness.

The circuit device of this embodiment will be described further in detail below. As shown in FIG. 1B, the conductive patterns 3 are embedded in and supported by the insulating resin 31, and rear surfaces thereof are exposed from the insulating resin 31. In this case, the conductive patterns 3 are formed of a conductive foil mainly made of Cu, a conductive foil mainly made of Al, a conductive foil made of alloys such as Fe—Ni, or the like.

As described later in detail, isolation trenches 32 are provided between the conductive patterns 3 by half etching, and the isolation trenches 32 are filled with the insulating resin 31, joined with sides of the conductive patterns and firmly bonded thereto. Specifically, the insulating resin 31 seals the entire circuit device 10, here, the semiconductor element 1, the passive element 6 and the bonding wire 8 while exposing the rear surfaces of the conductive patterns 3.

As the insulating resin 31, a thermosetting resin formed by transfer molding or a thermoplastic resin formed by injection molding can be adopted. To be more specific, a thermosetting resin such as an epoxy resin or a thermoplastic resin such as a polyimide resin and polyphenylene sulfide can be used. Moreover, as the insulating resin, all kinds of resin can be adopted as long as the resin is one hardened by use of a mold or one capable of covering by dipping or coating. In the package described above, the insulating resin 31 also has a function of supporting the entire circuit device as well as sealing the semiconductor element 1 and the like. As described above, the entire circuit device is sealed by the insulating resin 31. Thus, separation of the semiconductor element 1 from the conductive patterns 3 can be prevented.

The semiconductor element 1 is fixed to the surface of the conductive pattern 3 in the package region 20 by use of the insulating or conductive adhesive 9 according to usage. In addition, one end of the bonding wire 8 is thermocompression-bonded to the electrode pad, and the other end thereof is connected to the conductive pattern 3 or the passive element 6.

The passive element 6 is bonded with the adhesive 9 in the region where no conductive patterns 3 are disposed within the package region 20, in other words, bonded to the isolation trench 32. Note that the passive element 6 is bonded as described above only in terms of a manufacturing process. Accordingly, the passive element 6 is actually bonded to a portion of a conductive foil, the portion thereof being at a bottom of the isolation trench 32. The portion will be removed in a final structure.

Specifically, the isolation trench 32 is a part to be exposed as a rear surface of the insulating resin 31 in the end. Below the passive element 6, the adhesive 9 is exposed to the same surface as the rear surface of the conductive pattern 3. In other words, the passive element 6 is supported by the insulating resin 31.

One end of the bonding wire 8 is directly fixed to the electrode part 7 of the passive element 6, and the other end thereof is connected to any of the electrode pad of the semiconductor element 1, the conductive pattern 3, and the electrode part 7 of the other passive element 6.

Note that a thickness of the insulating resin 31 is controlled so as to cover up to about 100 μm from a top of the bonding wire 8 in the circuit device 10. This thickness can be increased or reduced in consideration for strength.

In this embodiment, the passive element 6 is disposed in a position lower than the semiconductor element 1 by the thickness of the conductive pattern 3. Thus, even in a structure of fixing the bonding wire 8 to the passive element 6 having a thickness (height) larger than that of the semiconductor element 1, the increase in the package thickness can be suppressed.

Moreover, for example, below the bonding wire 8 fixed to the passive element 6, a part of the conductive pattern 3 can be disposed. Thus, the wires intersecting with each other can be realized in the single layer structure.

The rear surface of the insulating resin 31, the rear surfaces of the conductive patterns 3, and a rear surface of the adhesive 9 bonded to the passive element 6 are aligned with each other. In addition, on the rear surfaces, an insulating resin 33 having openings in desired regions is provided. Thereafter, a conductive material such as solder is deposited on the exposed conductive patterns 3 to form back electrodes 34. Thus, the circuit device 10 is completed.

In this event, as solder which forms a part of the back electrode 34 and becomes connections with the package board, lead-free solder mainly made of tin can be employed. There is a small variety of lead-free solder, and there is not much difference in a melting point therebetween. Therefore, in the structure shown in FIG. 1B, if lead-free solder is also used as fixing means in the package, lead-free solder in the package is remelted when the package is fixed to the package board.

However, in this embodiment, the passive element 6 in the package is fixed by use of an adhesive material (the adhesive 9) which is never remelted, and electrical connections are realized by the bonding wires. In other words, lead-free solder can be used for the back electrode 34.

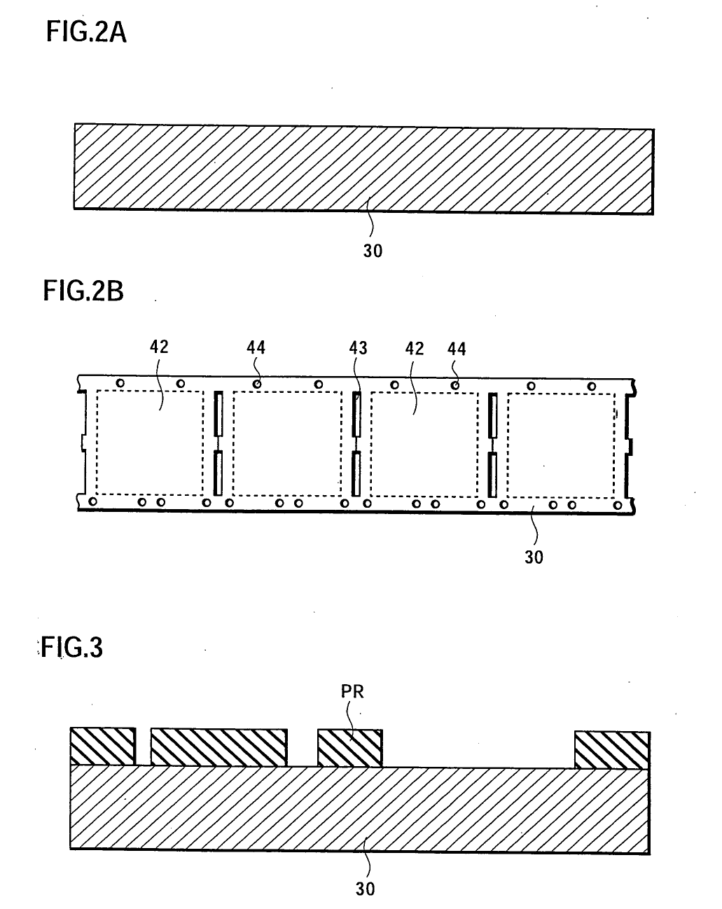

With reference to FIGS. 2 to 8, a method for manufacturing a circuit device according to an embodiment of the present invention will be described below.

The method for manufacturing a circuit device of the preferred embodiment includes the steps of: preparing a conductive foil, forming isolation trenches shallower than a thickness of the conductive foil in the conductive foil in a package region of a circuit element, and forming conductive patterns separated by the isolation trenches; fixing a passive element to the isolation trench; fixing one end of a bonding wire to an electrode part of the passive element, and fixing the other end thereof to a semiconductor element, the conductive pattern or another passive element; performing common molding by use of an insulating resin so as to entirely cover the package region of the circuit element and to fill the isolation trenches with the insulating resin; individually separating the conductive patterns by etching the conductive foil below the isolation trenches reach to the isolation trenches, and separating the passive element from the conductive pattern; and dividing the insulating resin for each package region of the circuit element by dicing.

The first step (see FIGS. 2 to 4): the step of preparing the conductive foil, forming the isolation trenches shallower than the thickness of the conductive foil in the conductive foil in the package region of the circuit element, and forming the conductive patterns separated by the isolation trenches.

First, as shown in FIG. 2A, a sheet-like conductive foil 30 is prepared. A material of this conductive foil 30 is selected in consideration for adhesion, bonding and plating properties of the adhesive 9. As the material thereof, a conductive foil mainly made of Cu, a conductive foil mainly made of Al, a conductive foil made of alloys such as Fe—Ni, or the like is employed. Moreover, other conductive materials can be also used. Particularly, a conductive material which can be etched is applicable.

A thickness of the conductive foil 30 may be about 10 μm to 300 μm in consideration for etching to be performed later. Here, a copper foil of 70 μm (2 oz) is employed. However, basically, the conductive foil may have a thickness of not less than 300 μm or not more than 10 μm. As described later, the conductive foil may have any thickness as long as the isolation trenches 32 shallower than the thickness of the conductive foil 30 can be formed.

Note that the sheet-like conductive foil 30 is prepared in a shape of a roll having a predetermined width, for example, 45 mm. This roll may be transferred to the respective steps to be described later. Alternatively, a strip of the conductive foil 30 may be prepared by cutting the foil into a predetermined size, and transferred to the respective steps to be described later.

Specifically, as shown in FIG. 2B, four or five blocks 42, in which a number of package regions 20 are formed, are arranged at even intervals in the strip of conductive foil 30. Between the respective blocks 42, slits 43 are provided to absorb stress on the conductive foil 30, which is caused by heat treatment in a molding step and the like. Moreover, in upper and lower peripheries of the conductive foil 30, index holes 44 are provided at even intervals, which are used for positioning in the respective steps.

Subsequently, the conductive patterns 3 for each block are formed.

First, as shown in FIG. 3, a photoresist (an etching-resistant mask) PR is formed on the Cu foil 30, and the photoresist PR is patterned so as to expose the conductive foil 30 except for regions to be conductive patterns 3.

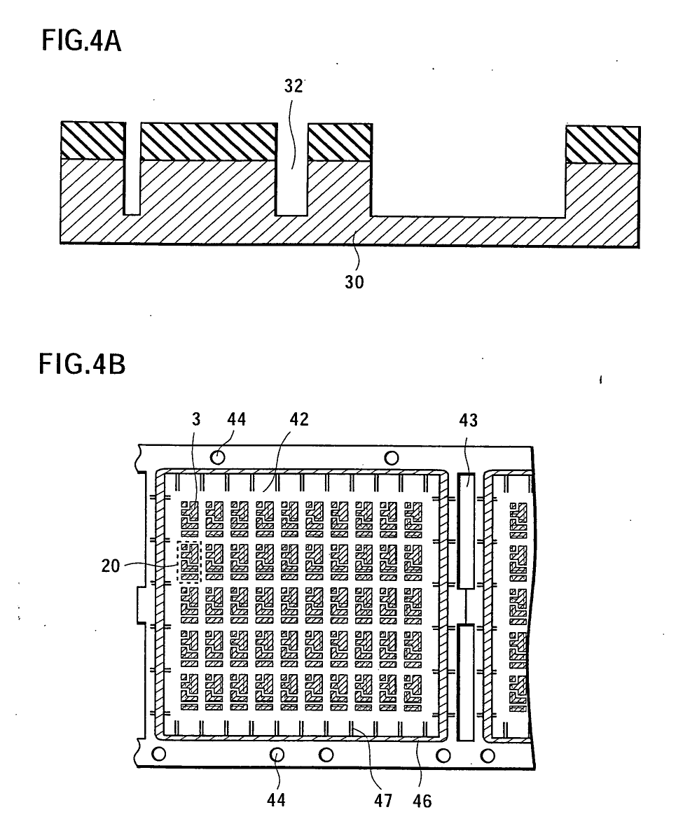

Thereafter, as shown in FIG. 4A, the conductive foil 30 is selectively etched through the photoresist PR.

A depth of the isolation trench 32 formed by etching is, for example, 50 μm, and the isolation trench 32 has a rough surface on its side or bottom. Thus, adhesion to the insulating resin 31 or the adhesive 9, which will be formed in the subsequent step, is improved.

Moreover, although a sidewall of the isolation trench 32 described above is schematically shown in a straight shape, the shape may differ depending on a removal method. As this removal method, wet etching, dry etching or dicing can be employed. In the case of wet etching, as an etchant, ferric chloride or cupric chloride is mostly used. The conductive foil is either dipped in this etchant or showered with this etchant. Here, in wet etching, non-anisotropic etching is generally performed. Thus, the side has a curved structure.

Moreover, in the case of dry etching, anisotropic or non-anisotropic etching can be performed. Cu can be removed by sputtering. Moreover, anisotropic or non-anisotropic etching can be performed depending on conditions of sputtering.

Note that, in FIG. 3, instead of the photoresist, a conductive film (not shown) which has corrosion resistance to the etchant may be selectively formed. If the corrosion-resistant conductive film is selectively deposited in a portion to be a conductive path, the film becomes an etching protective film. Accordingly, etching can be performed to form the isolation trench without using the resist. As a material of this conductive film, Ag, Ni, Au, Pt, Pd or the like can be used. Moreover, the corrosion-resistant conductive film described above has a characteristic that the film can be used as it is as a die pad and a bonding pad.

For example, a Ag film is bonded to Au. Thus, if an Au film is deposited on a rear surface of a chip, the chip can be directly thermocompression-bonded to the Ag film on the conductive pattern 3. Moreover, since a thin Au wire can be bonded to the Ag conductive film, wire bonding is possible. Therefore, there is an advantage that the conductive films described above can be directly used as the die pad and the bonding pad.

FIG. 4B shows a concrete example of the conductive pattern 3. FIG. 4B corresponds to an enlarged view of one of the blocks 42 shown in FIG. 2B. The conductive patterns 3 are hatched portions. Moreover, a region indicated by the broken line is the package region 20 which forms one circuit device 10. In each of the blocks 42, a number of the package regions 20 are arranged in a 5×10 matrix, for example. The conductive pattern 3 is provided for each of the package regions 20. A frame-like pattern 46 is provided around each block, and marks 47 for positioning in dicing are provided on an inner side of the pattern 46 with a small gap therebetween. The frame-like pattern 46 is used for joining with a mold, and also has a function of reinforcing the insulating resin 31 after etching a rear surface of the conductive foil 30.

The second step (see FIG. 5): the step of fixing the passive element to the isolation trench.

First, as shown in FIG. 5, the semiconductor element 1 is fixed to the conductive pattern (land) 3. Here, the bare semiconductor element 1 is die-bonded to the conductive pattern 3 by use of a conductive or insulating adhesive and the like.

Thereafter, the passive element 6 is bonded to the bottom of the isolation trench 32 by use of the insulating adhesive 9, for example. Note that the conductive adhesive 9 may be used as long as the adhesive is applied onto the respective electrode parts 7 so as to insulate the electrode parts 7 of the passive element 6 from each other. Here, a thickness t1 of the adhesive 9 is set to be larger than a height (t2) from a finishing line (X) of etching from the rear surface to a bottom of the passive element 6. Specifically, the finishing line is used in a subsequent step to separate the conductive foil 30 into the individual conductive patterns 3. Thus, in the subsequent step, the conductive foil 30 below the isolation trenches 32 is etched to individually separate the conductive patterns 3. In addition, in the step of exposing the rear surface of the conductive pattern 3, the passive element 6 is separated from the conductive pattern 3, and the adhesive 9 is exposed to the rear surface.

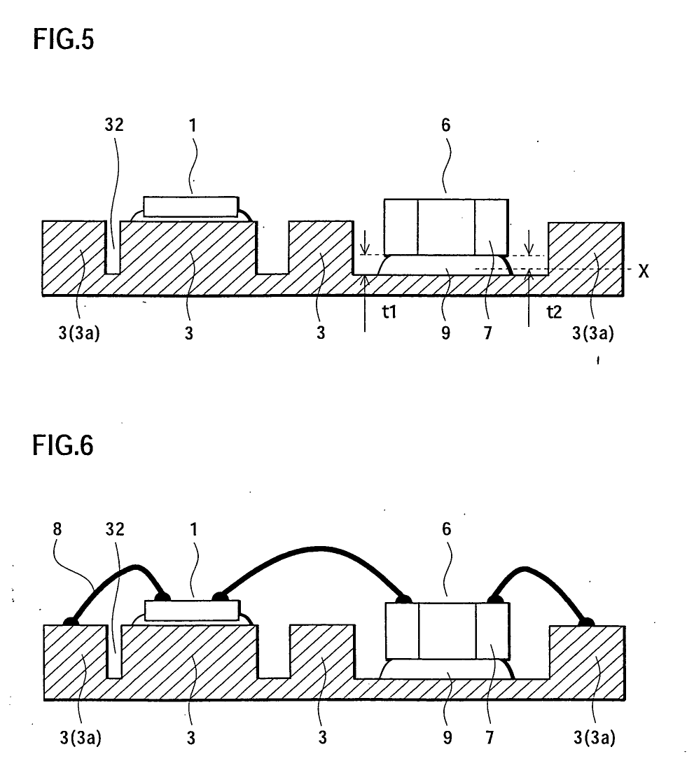

The third step (see FIG. 6): the step of fixing one end of a bonding wire to an electrode part of the passive element, and fixing the other end thereof to a semiconductor element, the conductive pattern or another passive element.

The electrode pad of the semiconductor element 1 is electrically connected to the desired conductive pattern 3. Specifically, the electrode pad and the pad part 3a of the conductive pattern 3 are connected to each other by thermocompression bonding of the bonding wire 8, such as Au and Al.

Moreover, in this embodiment, the passive element 6 is not fixed onto the conductive pattern 3. Therefore, electrical connections to the other constituent components are realized by use of the bonding wires 8. The electrode parts 7 of the passive element 6 are gold-plated and can be connected by thermocompression-bonding the bonding wire such as Au and Al. Thus, the mounting land part for fixing the passive element 6 is not required, and the wires can intersect with each other. Consequently, reduction in the mounting area can be realized.

Note that, in this embodiment, for the electrical connection of the passive element 6, the bonding wire such as Au and Al is used and subjected to thermocompression bonding. Accordingly, the same connection method is selected for the semiconductor element 1. However, without being limited thereto, the semiconductor element 1 may be fixed by use of other bonding wires by wedge bonding using supersonic waves.

Moreover, as described above, the passive element 6 is thicker than the semiconductor element 1. Thus, if the passive element 6 is fixed onto the conductive pattern 3, the package thickness may be increased due to the thickness of the passive element 6 itself, the loop height of the bonding wire 8, and the like. However, the thickness equivalent to that of the conductive pattern 3 can be reduced by fixing the passive element 6 to the isolation trench 32 as described above in this embodiment.

In this step, since a number of the conductive patterns 3 are integrated in each block 42, there is an advantage that fixing and wire bonding of the circuit devices 10 can be very efficiently performed.

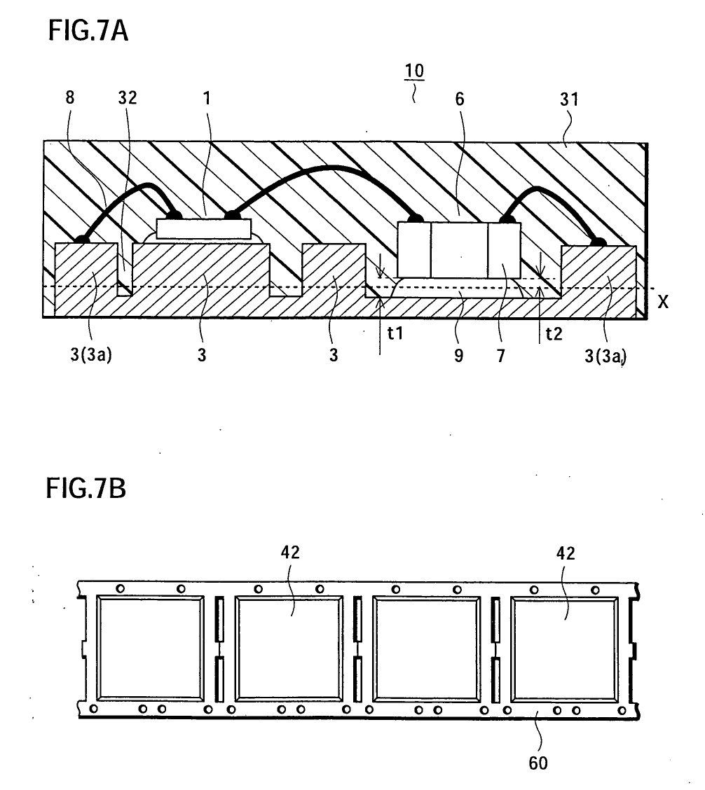

The fourth step (see FIGS. 7A and 7B): the step of performing common molding by use of an insulating resin so as to entirely cover the package region of the circuit element and to fill the isolation trenches with the insulating resin.

First, as shown in FIG. 7A, the insulating resin 31 completely covers the semiconductor element 1, the passive element 6, the conductive patterns 3, and the bonding wires 8 in the package region 20. Accordingly, the isolation trenches 32 between the conductive patterns 3 are filled with the insulating resin 31 so as to be joined with and firmly bonded to the curved structure on the sides of the conductive patterns 3. Thus, the conductive patterns 3 are supported by the insulating resin 31.

Moreover, this step can be realized by transfer molding, injection molding or dipping. As a material of the resin, a thermosetting resin such as an epoxy resin can be realized by transfer molding, and a thermoplastic resin such as a polyimide resin and polyphenylene sulfide can be realized by injection molding.

Furthermore, in transfer molding or injection molding in this step, as shown in FIG. 7B, the package regions 20 in the respective blocks 42 are housed in one common mold 60. Thereafter, common molding is performed by use of one insulating resin 31 for each block. Thus, compared to a method for individually molding the respective package regions, an amount of the resin can be significantly reduced, and the mold can be shared in common.

The thickness of the insulating resin 31 molded on the surface of the conductive foil 30 is controlled so as to cover up to about 100 μm from a top of the bonding wire 8 in the circuit device 10. This thickness can be increased or reduced in consideration for strength.

In this event, since the passive element 6 thicker than the semiconductor element 1 is bonded to the bottom of the isolation trench 32, the passive element 6 can be fixed in a position lower than the semiconductor element 1 by the thickness of the conductive pattern 3. Thus, an increase in a height of the top of the bonding wire 8 can be suppressed.

Moreover, until the insulating resin 31 is molded, the conductive foil 30 to be the conductive patterns 3 becomes a supporting substrate. The conductive foil 30 to be the supporting substrate is a necessary material as an electrode material. Thus, there is an advantage that operations can be performed while omitting as many formation materials as possible. Moreover, costs can also be reduced.

Moreover, since the isolation trenches 32 are formed to be shallower than the thickness of the conductive foil 30, the conductive foil 30 is not individually separated as the conductive patterns 3. Therefore, the sheet-like conductive foil 30 can be handled as a unit and is very easily transferred to and mounted on the mold in molding the insulating resin 31.

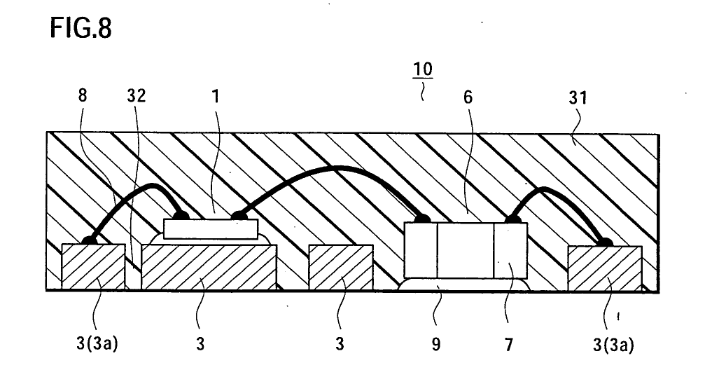

The fifth step (see FIG. 8): the step of individually separating the conductive patterns by etching the conductive foil below the isolation trenches reach to the isolation trenches, and separating the passive element from the conductive pattern.

In this step, until the conductive foil 30 below the isolation trenches 32 reaches the isolation trenches 32, in other words, up to the finishing line X of etching, which is indicated by the dotted line in FIG. 7A, the conductive foil 30 is wet-etched. In this event, the thickness t1 of the adhesive 9 is formed to be larger than the distance t2 from the bottom of the passive element 6 to the finishing line X of etching (FIG. 7A). Thus, by etching the conductive foil so as to individually separate the conductive patterns 3, the conductive foil 30 below the isolation trenches 32 is removed, the passive element 6 is separated from the conductive pattern 3, and the adhesive 9 is exposed to the rear surface of the insulating resin 31. Although the passive element 6 has the adhesive 9 bonded thereto, the conductive foil 30 that is the bonded material is removed. Thus, the passive element 6 is substantially supported by the insulating resin 31.

Moreover, as a result of this etching, the conductive patterns 3 are separated to have a thickness of about 40 μm, and the rear surfaces of the conductive patterns 3 are exposed to the insulating resin 31.

Specifically, the rear surface of the insulating resin 31 filled in the isolation trenches 32, the rear surfaces of the conductive patterns 3, and the rear surface of the adhesive 9 bonded to the passive element 6 are substantially aligned with each other. Therefore, the circuit device 10 of the preferred embodiment is horizontally moved as it is by surface tension of solder or the like in mounting thereof. Thus, self-alignment can be performed.

The sixth step (see FIG. 1B): the step of dividing the insulating resin for each package region of the circuit element by dicing.

Furthermore, a conductive material such as solder is deposited on the exposed conductive patterns 3 according to need. Thus, the back electrodes 34 are formed. For the back electrodes 34, lead-free solder, for example, can be employed. Thereafter, the insulating resin 31 is individually divided by dicing for each of the package regions 20. Thus, the circuit device 10 is completed.

Note that, in this embodiment, the description was given of the example in which the semiconductor element 1 is fixed onto the conductive pattern 3. However, without being limited thereto, for example, in the case of such a semiconductor element 1 as that having a floating substrate, the semiconductor element 1 may be fixed to the isolation trench 32 as in the case of the passive element 6.

1. A circuit device comprising:
conductive patterns embedded in an insulating resin;
a semiconductor element electrically connected to the conductive patterns;
bonding wires; and
a passive element which is embedded in a region of the insulating resin, other than a region where the conductive patterns are embedded, and has electrode parts provided on its both sides,
wherein a bottom of the passive element is positioned lower than a surface of the conductive pattern, and one end of the bonding wire is fixed to the electrode part of the passive element.

2. The circuit device according to claim 1, wherein the conductive patterns, the semiconductor element, the passive element, and the bonding wires are covered with and integrally supported by the insulating resin.

3. The circuit device according to claim 1, wherein an adhesive material is bonded to the bottom of the passive element.

4. The circuit device according to claim 1, wherein the adhesive material bonded to the bottom of the passive element and a rear surface of the conductive pattern are exposed to the same surface.

5. The circuit device according to claim 1, wherein the other end of the bonding wire is connected to any of the semiconductor element and the conductive pattern.

6. The circuit device according to claim 1, wherein the other end of the bonding wire is fixed to an electrode part of another passive element.

7. The circuit device according to claim 1, wherein the electrode part of the passive element is gold-plated.

8. The circuit device according to claim 1, wherein, below the bonding wire fixed to the passive element, a part of the conductive pattern is disposed.

9. A method for manufacturing a circuit device, comprising the steps of:
preparing a conductive foil, forming isolation trenches shallower than a thickness of the conductive foil in the conductive foil in a package region of a circuit element, and forming conductive patterns separated by the isolation trenches;
fixing a passive element to the isolation trench;
fixing one end of a bonding wire to an electrode part of the passive element, and fixing the other end thereof to any of a semiconductor element, the conductive pattern and another passive element;
performing common molding by use of an insulating resin so as to entirely cover the package region of the circuit element and to fill the isolation trenches with the insulating resin;
individually separating the conductive patterns by etching the conductive foil below the isolation trenches reach to the isolation trenches, and separating the passive element from the conductive pattern; and
dividing the insulating resin for each package region of the circuit element by dicing.

10. The method for manufacturing a circuit device according to claim 9, wherein the passive element has the adhesive material exposed by etching the conductive foil below the isolation trench.

11. The method for manufacturing a circuit device according to claim 9, wherein the conductive foil is made of any of copper, aluminum and iron-nickel alloy.

12. The method for manufacturing a circuit device according to claim 9, wherein the isolation trenches selectively formed in the conductive foil are formed by any of chemical etching and physical etching.

13. The method for manufacturing a circuit device according to claim 9, wherein the bonding wire is thermocompression-bonded to the electrode part of the passive element.
